(19) United States
(12) Patent Application Publication
(10) Pub. No.: US 2026/0107794 A1
(43) Pub. Date: Apr. 16, 2026

(54) DIRECT COPPER HETEROGENEOUS INTEGRATION

(71) Applicant: Applied Materials, Inc., Santa Clara, CA (US)

(72) Inventors: Robert MAY, Santa Clara, CA (US); Loic CONSTANTIN, Santa Clara, CA (US); Marvin Louis BERNT, Kalispell, MT (US); Sarah WOZNY, Austin, TX (US); Vincent DICAPRIO, Pleasanton, CA (US)

(21) Appl. No.: 19/357,052

(22) Filed: Oct. 13, 2025

Related U.S. Application Data
(60) Provisional application No. 63/708,216, filed on Oct. 16, 2024.

(51) Int. Cl. H01L 23/538; H01L 21/48; H01L 23/498; H01L 25/00

(52) U.S. Cl. CPC H10W 70/611; H10W 70/095; H10W 70/635; H10W 70/66; H10W 90/00

(57) ABSTRACT

The present disclosure relates to methods of forming interconnects to bond package assemblies together. In one embodiment, copper interconnects are used to bond a package assembly having an organic substrate core to other package assemblies or electronic devices having substrate cores which may include organic cores or inorganic cores, such as silicon, glass, or silicon carbide. In another embodiment, copper interconnects are used to bond a package assembly having an organic substrate core to other package assemblies having organic substrate cores. In another embodiment, a semiconductor package assembly comprising copper or copper alloy interconnects, as herein described.

### CROSS-REFERENCES TO RELATED APPLICATIONS

This application claims benefit of and priority to United States Provisional Patent Application Ser. No. 63/708,216, filed on Oct. 16, 2024, which is incorporated herein by reference in its entirety.

### BACKGROUND

### Field

Embodiments of the present disclosure generally relate to electronic interconnects and methods of connecting electronic devices or package assemblies using electronic interconnects. More specifically, embodiments described herein relate to semiconductor packaging and printed circuit board (PCB) assemblies and methods of connecting combinations of each using electronic interconnects, specifically copper or copper alloys.

### Description of the Related Art

Due to an ever-increasing demand for miniaturized electronic devices and components, the demand for faster processing capabilities with greater circuit densities imposes corresponding demands on the materials, structures, and processes used in the fabrication of such integrated circuit chips. Alongside these trends towards greater integration and performance, however, there exists the perpetual pursuit for reduced manufacturing costs.

As semiconductor technology continues to evolve, the push for miniaturization and enhanced performance has led to increasingly complex integration challenges. While advancements in processing speed and circuit density are critical, they must be balanced with practical considerations such as material compatibility and cost-efficiency. One of the key hurdles in achieving this balance lies in the ability to seamlessly integrate diverse semiconductor package assemblies. Manufacturing diverse semiconductor includes bonding devices of different materials to one another or to a common substrate. Difficulties often lie in bonding devices of different materials because each material may require a different bonding method or may negatively affect the bonding of another device.

Therefore, what is needed in the art are methods to integrate semiconductor package assemblies with other semiconductor package assemblies that are made with various materials.

### SUMMARY

The present disclosure generally relates to copper or copper alloy electronic interconnects and methods of connecting electronic devices or package assemblies using copper or copper alloy electronic interconnects.

In one embodiment, a method of forming an advanced package assembly is provided. The method includes forming a patterning layer over a first base structure, forming a first conductive layer within the formed patterning layer, removing the patterning layer after forming the first conductive layer, forming an outer dielectric layer over portions of the formed first conductive layer, depositing a second conductive layer over the outer dielectric layer and exposed portions of the first conductive layer, forming conductor features by removing a portion of the second conductive layer to expose a surface that comprises portions of the outer dielectric layer and portions of the second conductive layer, and bonding an electronic component to one or more of the conductor features using a copper alloy interconnect. The first base structure includes two or more core structures separated from one another by one or more vias, one or more redistribution layers (RDLs) formed over a surface of the core structure, wherein the one or more RDL layers comprise redistribution layer vias disposed therein, and an interconnect panel.

In another embodiment, an advanced package assembly is provided. The advanced package assembly includes a base structure. The base structure includes two or more core structures separated from one another by one or more vias, one or more redistribution layers (RDLs) formed over a surface of the core structure, wherein the one or more RDL layers comprise redistribution layer vias disposed therein, and an interconnect panel. The advanced package assembly includes an outer dielectric layer disposed over the base structure and one or more conductor features disposed in one or more gaps of the outer dielectric layer. The advanced package assembly includes a first electronic component comprising an inorganic material electrically connected to the base structure and a second electronic component comprising an organic material electrically connected to the base structure.

In yet another embodiment, a method of forming an advanced package assembly is provided. The method includes forming a first base package structure and bonding the first base package structure to a first electronic component using at least one copper alloy interconnect, wherein the first electronic component comprises an organic material. The method further includes bonding the first base package structure to a second electronic component using at least one copper alloy interconnect, wherein the second electronic component comprises an inorganic material.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, as the disclosure may admit to other equally effective embodiments.

FIG. 1 illustrates a base package structure, according to one or more embodiments of the disclosure.

FIG. 2 is a flow diagram that illustrates a method of connecting a package assembly having an organic substrate core to other package assemblies or electronic devices having substrate cores which may include organic cores or inorganic cores, according to one or more embodiments of the disclosure.

FIGS. 3A-3P are schematic, cross sectional views of a package assembly during formation of an advanced package assembly, according to one or more embodiments of the disclosure.

FIG. 4 illustrates an advanced package assembly including a plurality of copper alloy interconnects.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to semiconductor advanced package assemblies and methods of forming the same. Specifically, the disclosure relates to a method of combining at least two built up package assemblies together, such as at least three or more built up package assemblies. The method of combining two built up package assemblies together may include utilizing copper or copper alloy interconnects to connect the assemblies together. The combining process may include using copper or copper alloy direct bonding to bond layers of a first package assembly to layers of a second package assembly.

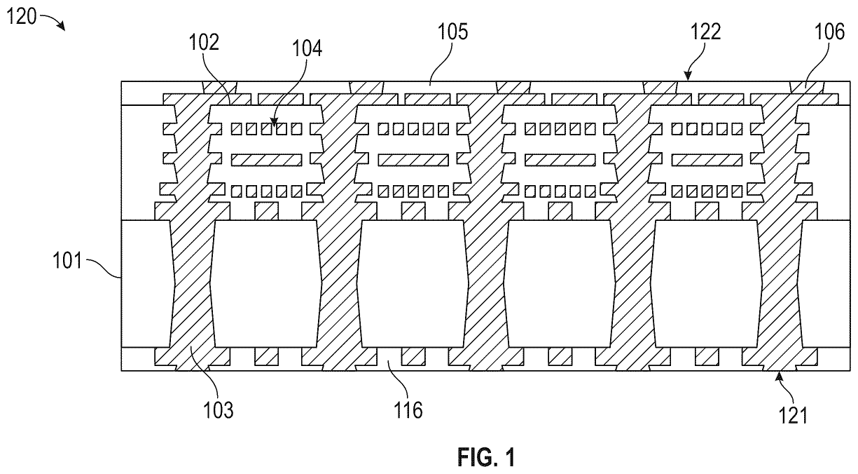

FIG. 1 illustrates a base package structure 120, according to one or more embodiments described herein. The base package structure 120 includes a core structure 101. The core structure 101 of the base package structure 120 may include organic cores or inorganic cores. The inorganic cores may include materials such as silicon, glass, or silicon carbide.

In one embodiment, the core structure 101 includes a patterned (e.g., structured) substrate formed of any suitable substrate material. A structured substrate may be a substrate that is intentionally modified or engineered to include specific physical features or patterns. In some embodiments, the core structure 101 includes a substrate formed from a III-V compound semiconductor material, silicon, crystalline silicon (e.g., Si<100> or Si<111>), silicon oxide, silicon germanium, doped or undoped silicon, doped or undoped polysilicon, silicon nitride, quartz, glass (e.g., borosilicate glass), sapphire, alumina, and/or ceramic materials. In one embodiment, the core structure 101 includes a monocrystalline p-type or n-type silicon substrate. In one embodiment, the core structure 101 includes a polycrystalline p-type or n-type silicon substrate. In another embodiment, the core structure 101 includes a p-type or an n-type silicon solar substrate. In another embodiment the core structure 101 may include a core substrate formed of a material that does not shrink much or does not shrink differentially during manufacturing processes, including heating of the core structure 101. The substrate utilized to form the core structure 101 may further have a polygonal, rectangular, or circular shape. For example, the core structure 101 may include a substantially square silicon, silicon carbide, or glass substrate having lateral dimensions between about 120 mm and about 550 mm, with or without chamfered edges. In another example, the core structure 101 may include a circular silicon-containing wafer having a diameter between about 20 mm and about 700 mm, such as between about 100 mm and about 50 mm, for example about 300 mm. The core structure 101 has a thickness T₁ between about 50 μm and about 1000 μm, such as a thickness T₁ between about 70 μm and about 800 μm.

The core structure 101 may further include one or more holes or core vias formed therein to enable conductive electrical interconnections to be routed through the core structure 101. Generally, the one or more core vias are substantially cylindrical in shape. However, other suitable morphologies for the core vias are also contemplated. The core vias may be formed as singular and isolated core vias through the core structure or in one or more groupings or arrays.

Generally, the one or more core vias may be formed by laser ablation (e.g. direct laser patterning). Any suitable laser ablation system may be utilized to form the one or more core vias. In some examples, the laser ablation system utilizes an infrared (IR) laser source. In some examples, the laser source is a picosecond ultraviolet (UV) laser. The laser source is configured to form any desired pattern of features in the substrate, including the core vias.

The core structure 101 includes an interconnect panel 116 disposed on one end of the core structure 101. The interconnect panel 116 comprises a material such as copper. The interconnect panel 116 provides a location to bond to other core structures 101 of other devices or substrates. A plurality of vias 103 are disposed between adjacent core structures 101. Adjacent core structures 101 are separated from one another by one or more vias 103. The vias 103 provide channels to electrically connect regions of the base package structure 120. In one embodiment, the vias 103 electrically connect a first major surface 121 of the base backage structure 120 to a second major surface 122 of the base package structure 120. In further embodiments, the vias 103 may protrude from a major surface 121, 122 of the base package structure 120. The vias 103 may be formed of any conductive materials used in the field of integrated circuits, circuit boards, chip carriers, and the like. For example, the vias 103 may be formed of a metallic material, such as copper, aluminum, gold, nickel, silver, palladium, tin, or the like.

Redistribution layers 102 may be formed on one or more surfaces of the core structure 101. The redistribution layers 102 may be formed using a modified semi-additive process, a semi-additive process, a damascene process, or any suitable patterning method. Any suitable patterning method may include ultraviolet (UV) photolithography, etching, and direct laser patterning.

In one embodiment, the redistribution layers 102 are formed of polymer-based dielectric materials. For example, the redistribution layers 102 are formed from a flowable build-up material. In a further embodiment, the redistribution layers 102 are formed of an epoxy resin material having a ceramic filler, such as silica (SiO₂) particles. Other examples of ceramic fillers that may be utilized to form the redistribution layers 102 include aluminum nitride (AlN), aluminum oxide (Al₂O₃), silicon carbide (SiC), silicon nitride (Si₃N₄, Sr₂Ce₂Ti_{2D16}, zirconium silicate (ZrSiO₄), wollastonite (CaSiO₃), beryllium oxide (BeO), cerium dioxide (CeO₂), boron nitride (BN), calcium copper titanium oxide (CaCu₃Ti₄O₁₂), magnesium oxide (MgO), titanium dioxide (TiO₂), zinc oxide (ZnO) and the like. In some examples, the ceramic fillers utilized to form the redistribution layers 102 have particles ranging in size between about 40 nm and about 1.5 μm, such as between about 80 nm and about 1 μm.

One or more redistribution layer vias 104 may be formed through the redistribution layers 102 where the redistribution layer 102 extends into the core vias of the core structure 101. For example, the redistribution layer vias 104 may be centrally formed within the core vias having the redistribution layers 102 disposed therein. Two or more of the redistribution layers 102 may comprise an interconnect structure that is electrically coupled to the vias 103.

The base package structure 120 includes an outer dielectric layer 105 disposed over the redistribution layer 102. The outer dielectric layer 105 may be disposed over portions of the vias 103. The outer dielectric layer 105 is connected to an upper surface of a redistribution layer 102. The outer dielectric layer 105 may be made of a material similar to the redistribution layer 102. In some embodiments, the outer dielectric layer 105 is formed from a flowable build-up material. In a further embodiment, the outer dielectric layer 105 is formed of an epoxy resin material having a ceramic filler, such as silica (SiO₂) particles

The base package structure 120 includes conductor features 106. As shown in FIG. 1, the conductor features 106 are disposed in gaps of the outer dielectric layer 105. The conductor features 106 may comprise a conductive material such as copper, copper alloys with silver, gold, indium, ruthenium, cobalt, or any combinations thereof.

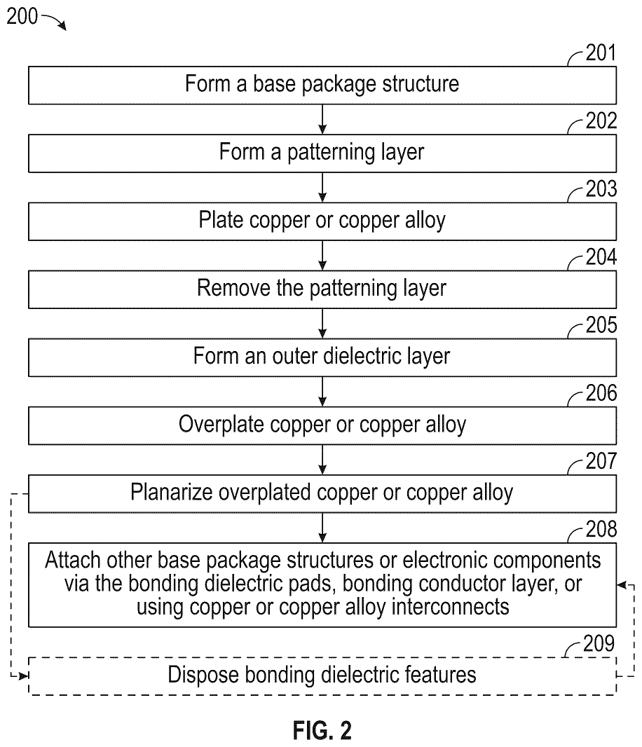

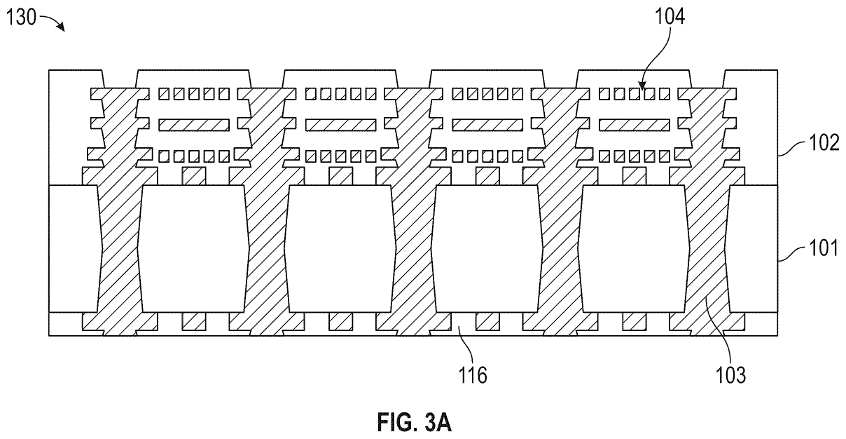

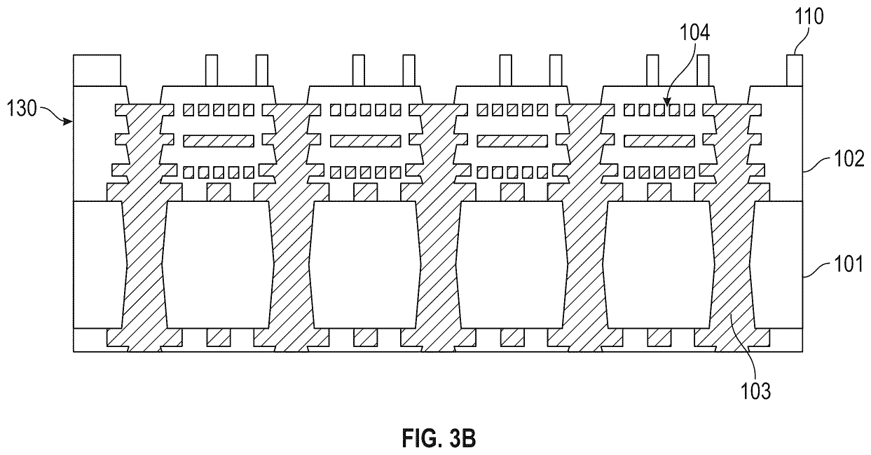

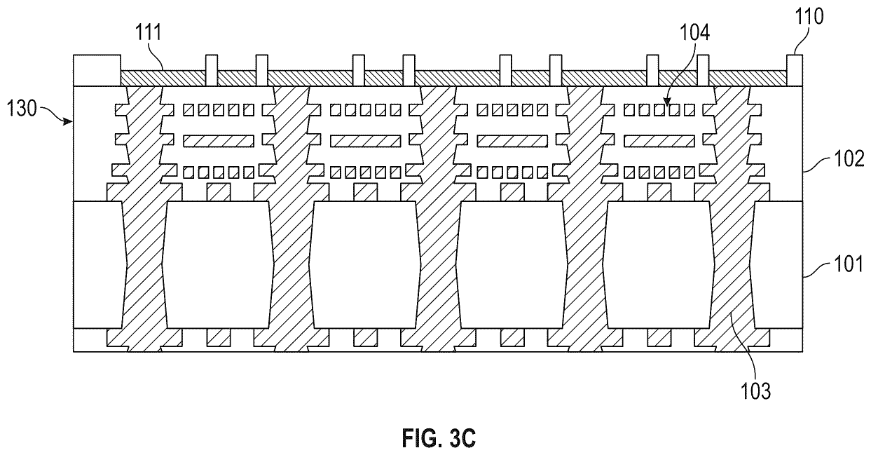

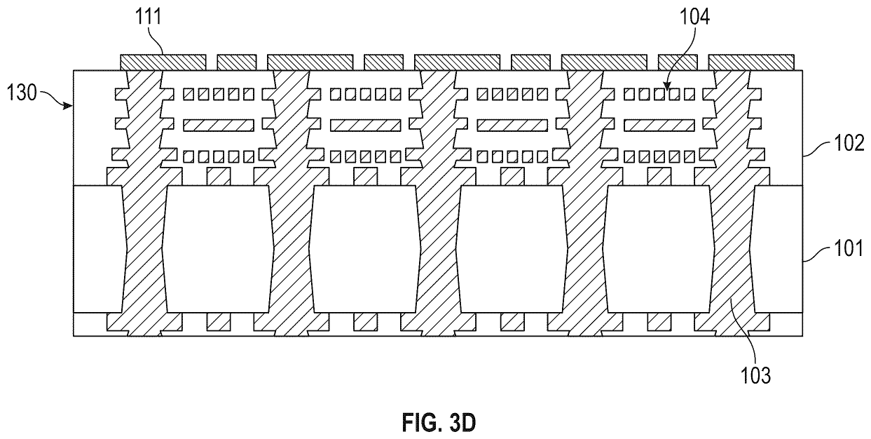

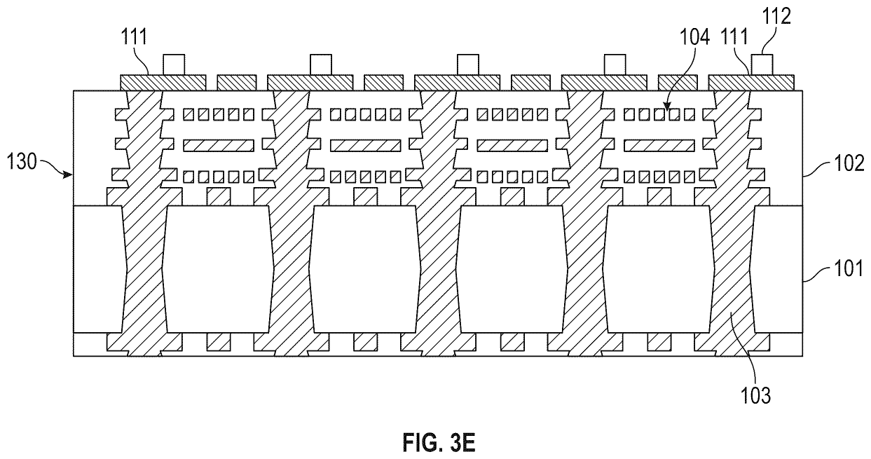

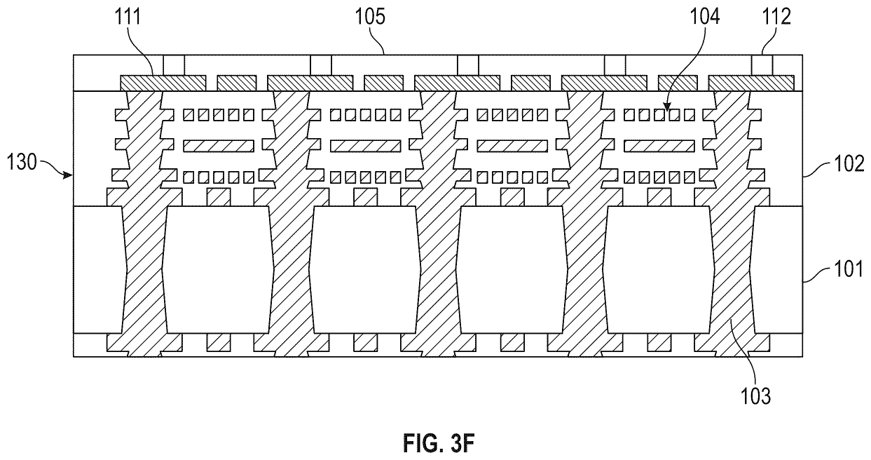

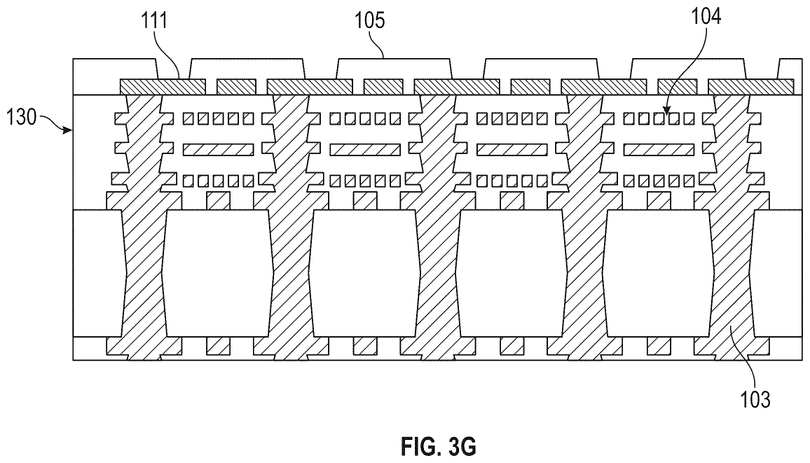

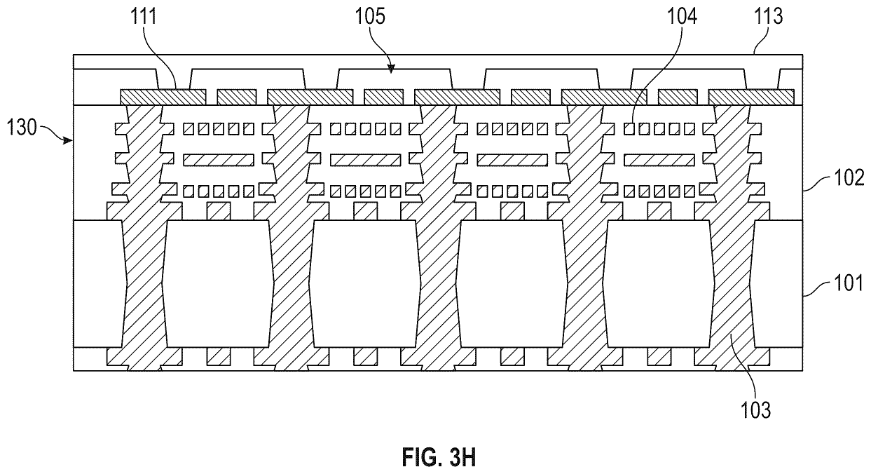

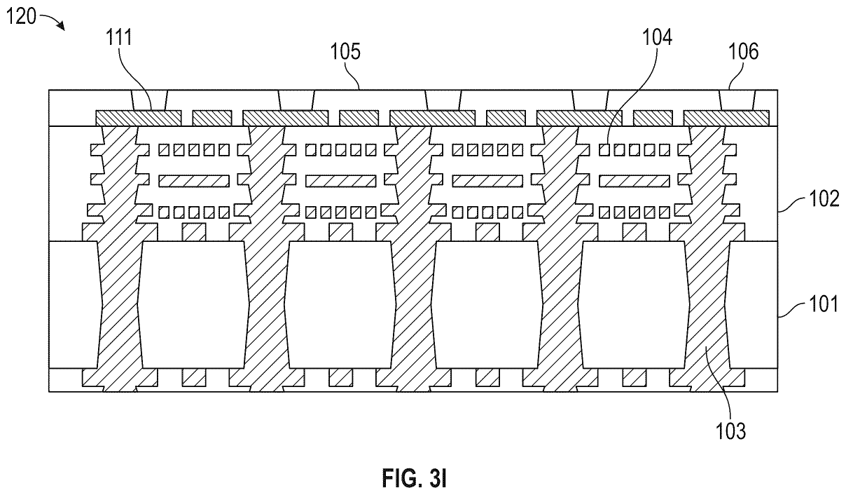

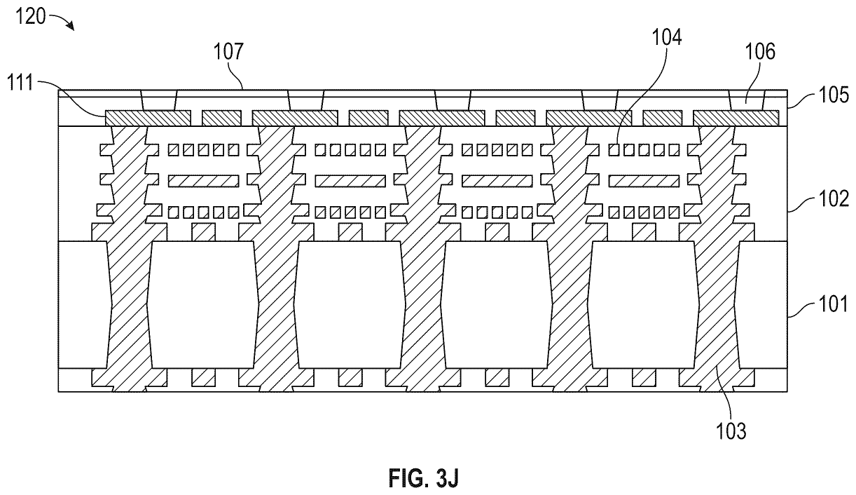

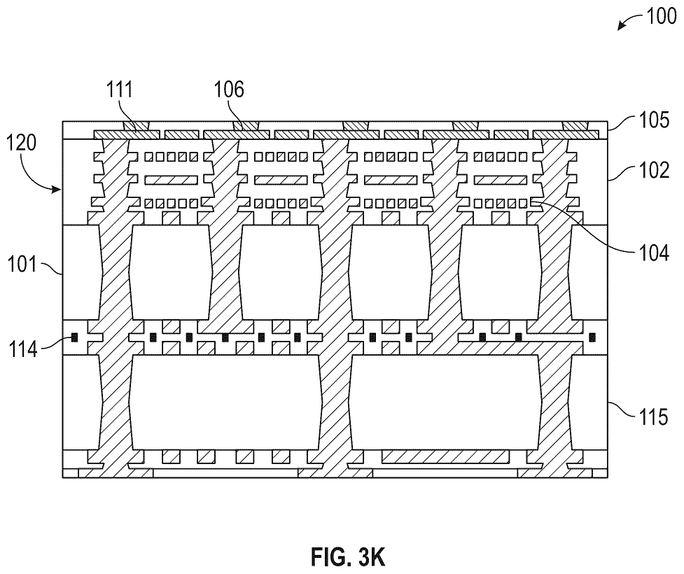

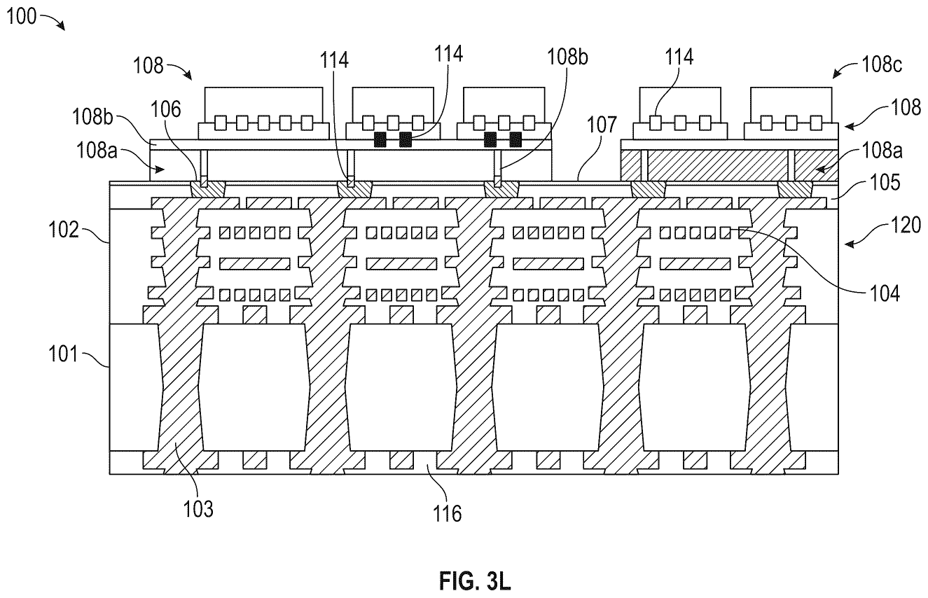

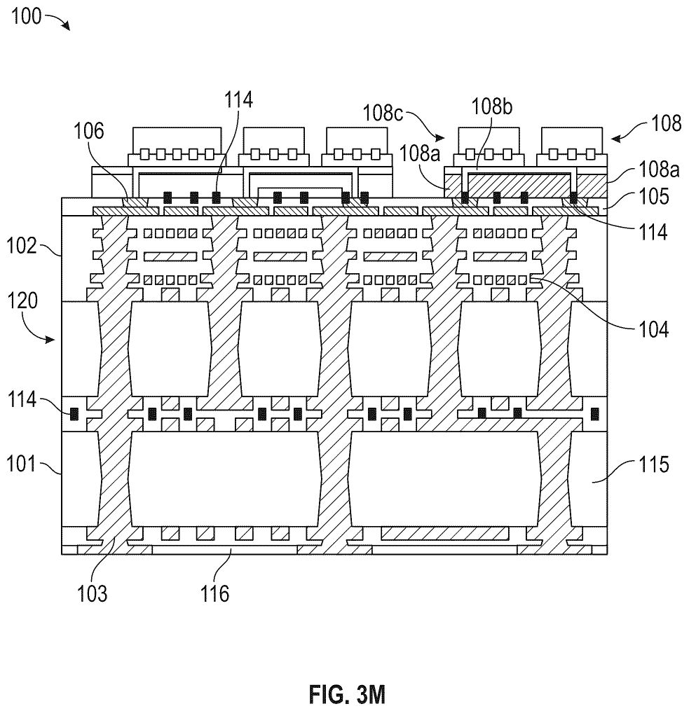

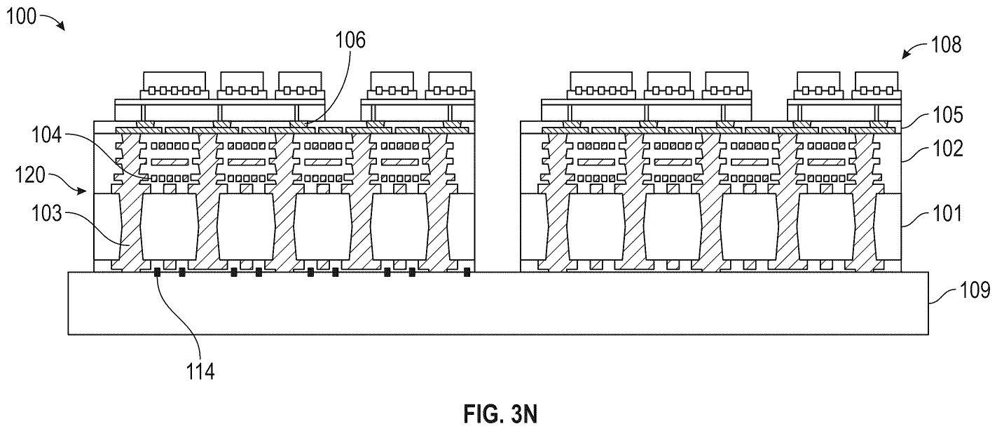

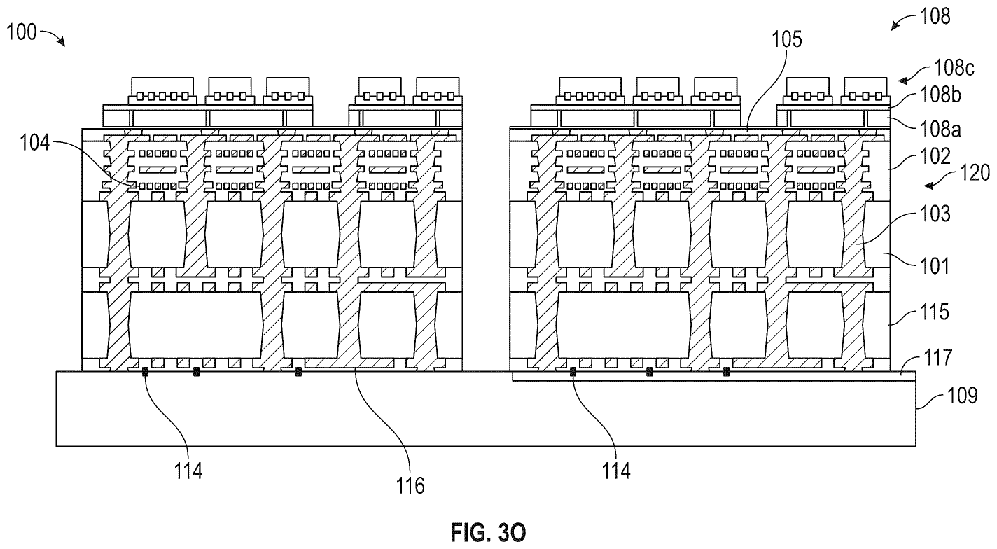

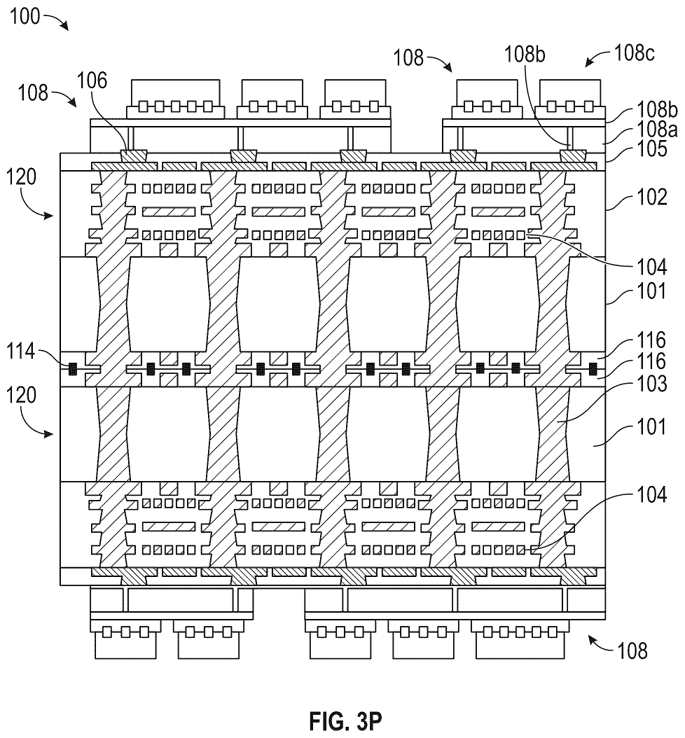

FIG. 2 is a flow diagram that illustrates a method of forming an advanced package assembly 100 having a base package structure 120 that includes a core structure 101 that can be coupled to other package assemblies or electronic components 108. The method 200 has multiple operations 201, 202, 203, 204, 205, 206, 207, and 208. Each operation is described in greater detail below. To facilitate explanation, the method 200 is described with reference to the advanced package assemblies 100 of FIGS. 3A-3P. In one example, the electronic components 108 can include a printed circuit board (PCB), an interposer, an integrated circuit (IC) containing substrate, a die-to-wafer (D2W) package, a die-to-package (D2P) assembly, a high-density-interconnector (HDI) PCB, a chiplet, or other useful pre-formed device structure or package.

The method 200 begins with forming a base structure 130 at operation 201, as shown in FIG. 3A. The base structure 130 may be utilized for structural support and electrical interconnection layers formed thereon. In further examples, the base structure 130 may be utilized as a carrier structure for a surface-mounted device, such as a chip or graphics card. The base structure 130 may comprise a core structure 101, redistribution layers 102, vias 103, redistribution layer vias 104, and an interconnect panel 116.

At operation 202, as shown in FIG. 3B, a patterning layer 110 is formed on a surface of the base structure 130. The patterning layer 110 may be formed using any suitable patterning process including UV photolithography, etching, and direct laser patterning. The patterning layer 110 may be made of material similar to that of the redistribution layers 102 formed in the base structure 130. In one example, the patterning layer 110 can include a resist material deposited over the surface of the base structure 130. In one process example, a direct laser patterning process is used which includes the use of a dynamic digital correction (DDC) process on one or more regions of the surface layer to compensate for asymmetric shrinkage or variation in the base package layer, and thus ensure good alignment of the formed pattern to the underlying elements formed within the base structure 130. The DDC process will include the use of an optical inspection device (e.g., one or more cameras) to, in real-time, detect and correct for variations in the alignment of the formed pattern (e.g., variations in prior formed underlying redistribution layers 112) during the direct laser patterning process. The variations in the exposed portions of prior-formed underlying redistribution layers 112 can include, for example, variations in pad locations and/or part-to-part variation in bump locations due to differential shrinkage of the core structure during prior fabrication processes.

At operation 203, as shown in FIG. 3C, a copper plating layer 111, or first conductive layer, is formed in the gaps between the features of the patterning layer 110. The copper plating layer 111 may be made of copper or a copper alloy. The copper plating layer 111 may be formed by use of electroplating process that forms a copper layer over a copper seed layer that is formed over surfaces of the gaps between the features of the patterning layer 110. The electroplating process may include any suitable deposition method including physical vapor deposition (PVD) and chemical vapor deposition (CVD).

At operation 204, as shown in FIG. 3D, the patterning layer 110 is removed from the surface of the base structure 130. The patterning layer 110 may be removed by an ashing and/or etching process.

At operation 205, as shown in FIGS. 3E-3G, an outer dielectric layer 105 is formed on a surface of the base structure 130. The outer dielectric layer 105 may be deposited over portions of the copper plating layer 111. The outer dielectric layer 105 may be formed in the gaps between the copper plating layer 111 created by the removal of the patterning layer 110, which was formed therebetween. The outer dielectric layer 105 may also be formed in pads above the copper plating layer 111. The outer dielectric layer 105 may be formed by any suitable patterning or deposition method. In one embodiment, the outer dielectric layer 105 may be formed of a dielectric material, such as a photoimageable polyimide or a non-photoimageable flowable buildup material such as a filled epoxy resin. The outer dielectric layer 105 may be formed over portions of the conductive layer 111 such that certain exposed portions of the conductive layer 111 are formed.

The outer dielectric layer 105 may be formed by depositing a photomask 112 over the copper plating layer 111, as shown in FIG. 3E. The photomask 112 may be formed by any suitable deposition method such as PVD, CVD, or ALD. Further, the outer dielectric layer 105 is deposited between the photomasks 112, as shown in FIG. 3F. After the outer dielectric layer 105 is deposited, the photomasks 112 are removed, as shown in FIG. 3G.

At operation 206, as shown in FIG. 3H, an overburden copper layer 113, or second conductive layer, is disposed on the top surface of the base structure 130. The overburden copper layer 113 may be formed by use of a copper electroplating process. The copper or copper alloy overplating results in an amount of copper or copper alloy that extends above the top surface of the outer dielectric layer 105.

At operation 207, as shown in FIG. 3I, the overburden copper layer 113 above the top surface of the outer dielectric layer 105 is removed via a planarization process so that the overburden copper layer 113 has a top surface in an equivalent plane with the outer dielectric layer 105. The planarization exposes a surface of the outer dielectric layer. The planarization of the overburden copper layer 113 forms bonding conductor features 106. The planarization process may include any suitable methods of planarizing such as a chemical mechanical polishing (CMP) process, mechanical grinding, fly-cutting or chemical etching. An additional conductive layer may be disposed over the outer dielectric layer 105. The additional conductive layer may increase the potential surface area for bonding points to other components.

Optionally, after the overburden copper layer 113 is planarized, bonding dielectric features 107 are disposed over the advanced package assembly 100, as shown in FIG. 3J. The bonding dielectric features 107 may be formed by any suitable patterning process including UV photolithography, etching, and direct laser patterning. The bonding dielectric features 107 may be formed of any suitable bonding dielectric material, such as silicon (Si), silicon carbide (SiC), silicon oxide (SiOx), an adhesive material, organic material, or other material that can promote bonding between components. In some embodiments, the bonding dielectric material 107 features may selectively bond to the top surface of the outer dielectric layer 105 and not directly on the top surface of the conductor features 106.

The base structure 130 after operation 307 including bonding conductor features 106 as shown in FIG. 3I (and optionally bonding dielectric features 107 as shown in FIG. 3J) is hereinafter referred to as the base package structure 120. The base package structure 120 is used to form various configurations of advanced package assemblies 100 as described below.

FIGS. 3K-3P illustrate various embodiments of advanced package assemblies 100 formed from a base package structure 120 and one or more direct copper interconnects. These embodiments demonstrate how direct copper bonding facilitates the integration of a wide range of materials. The various materials bonded together include both inorganic and organic materials. These embodiments also demonstrate how direct copper bonding facilitates the integration of a wide variety of device types. The various device types may include inorganic, organic, and several other device types. This bonding approach not only assists in precise alignment between components, but also enables multiple different electrical connections to be formed within a single advanced package assembly 100, thereby minimizing the overall footprint of the advanced package assembly 100 while being able to perform multiple functions.

The versatility of the copper bonding interconnects is enhanced through the use of heterogeneous copper interconnects. Unlike homogeneous copper, heterogeneous copper, such as structured copper or copper alloys, supports multiple bonding types within the same assembly. The multiple bonding types that are supported include copper to copper, solder to copper, and solder to solder interfaces. This capability allows for the creation of mixed bonding architectures that can accommodate thermal, mechanical, and electrical requirements across layers. Moreover, the use of heterogenous copper reduces the need for multiple discrete advanced package assemblies 100 to be formed to each perform different functions. Instead, the use of these heterogenous copper interconnects allows for an advanced package assembly 100 to be formed of multiple devices and components that perform different functions.

At operation 208, electronic components 108 may be bonded to the surface of the bonding dielectric features 107 and/or the bonding conductor features 106 of the base package structure 120. In some embodiments, other advanced package assemblies 100 may be bonded to the surface of the bonding dielectric features 107 and the bonding conductor features 106 of the base package structure 120. In some embodiments, the advanced package assemblies 100 may have core structures 101 with substrate cores made of organic materials, silicon, glass, silicon carbide, and/or materials that do not shrink by a large amount or do not shrink differentially during manufacturing processes. In some embodiments, the advanced package assemblies 100 may have core structures 101 with substrate cores made of inorganic materials. The electronic components 108 bonded to the surface of the bonding dielectric features 107 and the bonding conductor features 106 may include bridges, dies, chips, graphic cards, or any combinations thereof. In some embodiments, the base package structure 120 may be bonded to an identical base package structure 120. Any of the above bonding combinations or those described hereafter may be performed at a temperature from about 150° C. to about 250° C.

In some embodiments, other advanced package assemblies 100 may be bonded by copper or copper alloy interconnects 114 to the first advanced package assembly 100. In some embodiments, the advanced package assemblies 100 are bonded to one another via copper alloy interconnects 114 between the core structures 101 of the two advanced package assemblies 100. The copper or copper alloy interconnects 114 may bond in several positions between the core structures 101. Additionally, in embodiments where the package assemblies are not bonded between the core structures 101, the package assemblies may be bonded via the copper or copper alloy interconnects 114 via various other positions of the advanced package assemblies 100.

The advanced package assembly 100 is bonded to the other advanced package assemblies 100 via the copper or copper alloy interconnects 114 by first aligning conductor features 106, copper alloy interconnects 114, or other bonding interface of each advanced package assembly 100 that are to be bonded together. Once the panels 116 are aligned, the panels 116 are bonded together via copper or copper alloy direct bonding. This method of direct copper bonding may also be used to bond the advanced package assembly 100 to other components or devices. Accordingly, the entire advanced package assemblies 100 are bonded together through the panels 116 of each being bonded to one another. Copper or copper alloy direct bonding may occur in several locations along the panel 116. After the advanced package assemblies 100 are bonded together via copper direct bonding, the resulting advanced package assembly 100 may be further bonded to other advanced package assemblies 100. The advanced package assemblies 100 may be bonded to one another via a package substrate 109. The direct copper or copper alloy bonding enables multiple layers and advanced package assemblies 100 of varying materials to be bonded together to create complex advanced package assemblies 100 comprising a multitude of materials and component types. The panels 116 being bonded may be the same size or cut down into different sized sub panels (still containing multiple units) or units based on the process requirements.

FIG. 3K illustrates an embodiment of an advanced package assembly 100 including a base package structure 120 bonded to an additional core structure 115. The additional core structure 115 may be made of any material. The base package structure 120 is bonded to the additional core structure 115 by direct copper bonding as described above. In some embodiments, the base package structure 120 may be bonded to the additional core structure 115 via one or more copper alloy interconnects 114.

FIG. 3L illustrates an embodiment of an advanced package assembly 100 including a base package structure 120 bonded to electronic components 108. The electronic components 108 may be any of the electronic components 108 described above. The base package structure 120 is bonded to the electronic components 108 by direct copper bonding as described above.

FIG. 3L illustrates an advanced package assembly 100 including one base package structure 120 bonded to electronic components 108, according to one or more embodiments of the disclosure. The electronic components 108 may include a component substrate 108a. The component substrate 108a may comprise an organic or inorganic material. As shown in FIG. 3L, one component substrate 108a may comprise a material different than another component substrate 108a bonded to the base package structure 120. For example, one component substrate 108a may comprise an organic material and one component substrate 108a may comprise an inorganic material. The use of copper or copper alloy interconnects assists in the bonding of the multiple types of component substrates 108a to the same base package structure 120.

The electronic components 108 may include a component via 108b disposed within the component substrate 108a and coupled to an active component 108c of the electronic component 108. Portions of the component via 108b may be disposed outside of the component substrate 108a. In one or more embodiments, a portion of the component via 108b is disposed over an upper surface of the component substrate 108a to increase the contact areas to the active component 108c. The component via 108b comprises copper. The component via 108b is aligned and bonded to a conductor feature 106 of the base package structure 120.

The active component 108c may include a die, complete integrated circuit, or any functional component. In some embodiments, the active component 108c is a central processing unit (CPU) die, memory die, graphics processing unit (GPU) die, application-specific integrated circuit (ASIC) die, bare die, or chiplet die. The advanced package assembly 100 may include different types of active components 108c. Including multiple active components 108c on the same advanced package assembly 100 decreases the overall size needed for a certain end device by fitting more components on a single device that would traditionally need to be placed on separate advanced package assemblies 100. Additionally, processing speeds may increase because of the shorter distances between active components 108c that communicate with one another when they are positioned on the same advanced package assembly 100. The active component 108c may be bonded to the component substrate 108a by utilizing copper alloy interconnects 114. As shown in FIG. 3L, the active component 108c may be bonded to the component via 108b.

FIG. 3L illustrates a bonding dielectric feature 107 disposed over an outer dielectric layer 105. In one or more embodiments, the conductor features 106 are disposed through the bonding dielectric feature 107 to ensure an electrical connection between the base package structure 120 and the one or more electronic components 108 is made, as shown in FIG. 3L. In one or more embodiments, the bonding dielectric features 107 are disposed over the conductor features 106 in embodiments including dielectric features 107 (shown in FIG. 3J).

FIG. 3M illustrates an embodiment of an advanced package assembly 100 including a base package structure 120 bonded to electronic components 108 and an additional core structure 115. The embodiment shown in FIG. 3M may be formed by bonding electronic components 108 to the advanced package assembly 100 of FIG. 3K. Additionally, the embodiment shown in FIG. 3M may be formed by bonding an additional core structure 115 to the advanced package assembly 100 of FIG. 3L.

FIG. 3M illustrates an advanced package assembly 100 including one base package structure 120 bonded to additional substrate cores 115 at one end and bonded to electronic components 108 at another end, according to one or more embodiments of the disclosure. In one or more embodiments, a copper alloy interconnect 114 is used to bond the outer dielectric layer 105 to the electronic component 108. In one or more embodiments, a copper alloy interconnect 114 is used to bond the conductor features 106 to the electronic component 108. The additional substrate cores 115 may include interconnect panels 116 to assist in further bonding to other devices. The additional substrate cores 115 may be bonded to the base package assembly 120. Bonding the additional substrate cores 115 to other components may include utilizing copper alloy interconnects 114.

FIG. 3N illustrates an embodiment of an advanced package assembly 100 including two base package structures 120 bonded to the same package substrate 109. As shown in FIG. 3N, each of the base package structures 120 may include electronic components 108 bonded thereto, such as the advanced package assembly shown in FIG. 3L. The package substrate 109 may be made of any suitable material. Each base package structure 120 is bonded to the package substrate 109 by aligning and using direct copper bonding as described throughout. In one or more embodiments, one or more of the base package structures 120 is bonded to the package structure via copper alloy interconnects 114.

FIG. 3O illustrates an advanced package assembly 100 including one base package structure 120 bonded to additional substrate cores 115 and a package substrate 109 at one end and bonded to electronic components 108 at another end, according to one or more embodiments of the disclosure. In addition, FIG. 3O shows two of the advanced package assemblies 100 of FIG. 3M bonded to a common package substrate 109. The package substrate 109 may comprise any suitable material. In one or more embodiments, the package substrate 109 is made of a polyimide, ceramics, glass, metals, silicon interposers, or combinations thereof. The package substrate 109 may comprise structure bonding features 117 as shown on the right side of the package substrate 109. The structure bonding features 117 may be made of a material that assists in the bonding to the interconnect panel 116. In these embodiments, the interconnect panels 116 are aligned and bonded to bond the advanced package assemblies 100 of FIG. 3M to the package structure 109. In one or more embodiments, the structure bonding features 117 are made of a copper alloy material and the interconnect panel 116 is made of a copper alloy material. In these embodiments, a direct copper bonding process may be used to bond the base package structure 120 to the package substrate 109. In this embodiment, the use of the copper alloy bonding allows components of various materials to be bonded to one another. For example, copper alloy interconnects 114 may be used to bond the base package structure 120 to a package substrate 109.

FIG. 3P illustrates an advanced package assembly 100 including two individual advanced package assemblies 100 bonded to one another and electronic components 108 bonded to two ends of the advanced package assembly 100, according to one or more embodiments of the disclosure. As shown in FIG. 3P, the two individual advanced package assemblies 100 may be the advanced package assemblies 100 shown in FIG. 3M. The two base package structures 120 may be bonded to one another by aligned interconnect panels 116 of each base package structure 120. The aligned interconnect panels 116 of each base package structure 120 may be bonded to one another using copper alloy interconnects 114. The copper alloy interconnects may assist in alignment of the panels through use of dynamic digital correction (DDC).

DDC enables precise and reliable bonding of various components of the advanced package assembly 100. DDC compensates for part-to-part variations in bump or pad locations, which are especially pronounced in organic-based substrates due to their nonlinear shrinkage behavior in the X/Y dimensions during processing. By digitally mapping and correcting these positional deviations, DDC ensures that copper or copper alloy pads on opposing surfaces are accurately aligned prior to bonding. This correction is critical for achieving high-yield direct copper bonding across heterogeneous materials and layers, including silicon, glass, and organic substrates. Without DDC, bonding an organic material with an inorganic material may result in misalignment because of the organic material shrinking during processing. Thus, DDC is used to align two different components prior to bonding.

For example, the interconnect panel 116 of a first base structure 130 may be aligned with the interconnect panel 116 of a second base structure 130 using DDC. The first base structure 130 may comprise a different material than the second base structure 130 and accordingly shrink at a different rate than the second base structure 130. DDC may be used to align copper alloy interconnects 114 within each of the interconnect panels 116 to one another using DDC. This ensures that after the bonding process, the copper alloy interconnects 114 remain aligned for a secure connection between the first base structure 130 and the second base structure 130. After DDC is utilized to account for this difference in shrinkage and the interconnect panels 116 are properly aligned, the interconnect panels 116 are bonded to one another to form the resulting advanced package assembly 100.

The bonding process includes controlling the temperature and pressure such that the copper alloy interconnects 114 bond to one another to form a single component structure. The copper alloy interconnects 114 may be added to the surfaces of each of the components that are to be bonded to one another. In these embodiments, the copper alloy interconnects 114 function as eutectics.

It should be appreciated that the above methods of bonding and DDC are not limited to the example provided above and are equally applicable to all embodiments described herein.

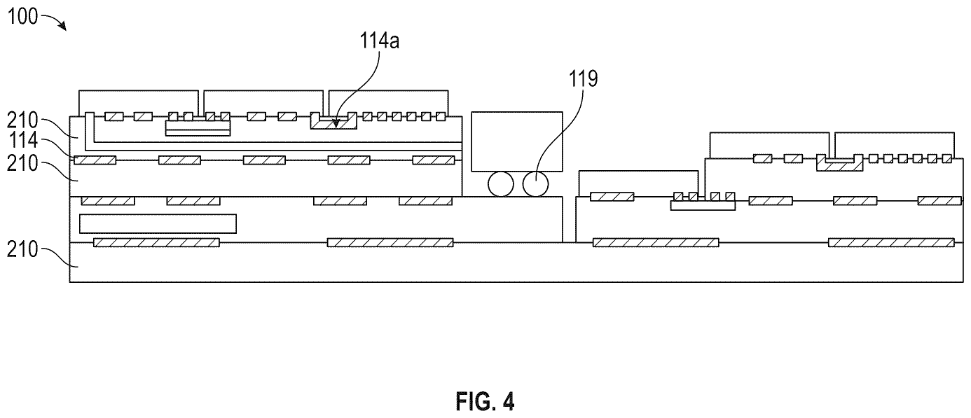

FIG. 4 illustrates an advanced package assembly 100 including a plurality of copper alloy interconnects 114. The copper alloy interconnects 114 are used to form a bond between distinct components 210 of the advanced package assembly 100, as shown in FIG. 4. Each of the components 210 may be any of the above described components such as the redistribution layer 102, the outer dielectric layer 105, the bonding conductor features 106, or the electronic component 108, as shown in FIGS. 3K-3P.

As shown in FIG. 4, additional connections may also be present throughout the advanced package assembly 100. For example, a solder connection 119 may also be present within the advanced package assembly 100. The use of copper alloy interconnects 114 does not impede the use of other connections within the advanced package assembly 100. The copper alloy interconnects 114 may be used to form bonds between components vertically stacked on one another. Additionally, copper alloy interconnects 114 may be used to form bonds between components positioned horizontally adjacent to one another. An example of the horizontal connection can be seen with the horizontal copper alloy interconnect 114a shown in FIG. 4.

in the embodiments described above, the copper alloy interconnects 114 and conductor features 106 enable connections between devices, components, and substrates of different types. The versatility of the copper alloy interconnects 114 and the conductor features 106 streamlines processing by providing a uniform processing environment for bonding components to one another. For example, the copper alloy interconnects 114 and conductor features 106 are made of a material that allows metallurgical bonding at a temperature range from about 150° C. to about 250° C. Organic materials often degrade at high temperatures. However, at a temperature range from about 150° C. to about 250° C. the organic materials do not degrade and can be bonded to other devices, components, and substrates via the direct copper bonding. The versatility of the copper bonding process allows for the creation of more complex devices that include combinations of different types of electronic components bonded to one another in a single chip. Additionally, DDC enables the formation of high-density advanced package assemblies 100 without the need for underfill, allowing for more flexible and scalable system designs while also reducing assembly complexity and cost.

### Examples of Methods of Forming Advanced Package Assemblies

Embodiments of the disclosure include a method of forming an advanced package assembly, comprising: depositing a first conductive layer over a surface of and within features formed in a patterned dielectric layer that is formed over a first base structure, wherein the first base structure comprises a core structure over which the patterned dielectric layer is formed; forming conductor features by removing a portion of the first conductive layer, wherein removing the portion of the first conductive layer exposes the surface of the patterned dielectric layer and portions of the first conductive layer formed within the features formed in the patterned dielectric layer; depositing a second conductive layer on exposed surfaces of the first conductive layer formed within the features, wherein the first conductive layer comprises copper, and the second conductive layer comprises an alloy of copper; and forming a bond between an electrical contact of an electronic component and the second conductive layer, wherein the electrical contact comprises copper.

Embodiments of the disclosure include a method of forming an advanced package assembly, comprising: depositing a first conductive layer over a patterned dielectric layer formed over a first base structure, wherein the first base structure comprises: a core structure that comprises one or more vias; and one or more redistribution layers formed over a surface of the core structure, wherein the one or more redistribution layers comprise a conductive redistribution layer disposed over the one or more vias, and wherein the first conductive layer is formed on exposed portions of the conductive redistribution layer disposed within features formed in the patterned dielectric layer. Then forming conductor features by removing a portion of the first conductive layer disposed over the patterned dielectric layer to expose surfaces of the patterned dielectric layer and portions of the first conductive layer formed within the features formed in the patterned dielectric layer; depositing a third conductive layer on the exposed surfaces of the first conductive layer formed within the features formed in the patterned dielectric layer, wherein the first and second conductive layers each comprise copper; and then forming a bond between an electrical contact of an electronic component and the second conductive layer, wherein the electrical contact comprises copper. In one embodiment, the second conductive layer has a melting point that is less than a melting point of the first conductive layer. In another embodiment, the first conductive layer comprises copper and the second conductive layer comprises an alloy of copper.

Embodiments of the disclosure include a method of forming an advanced package assembly, comprising: forming a patterning layer over a first base structure, wherein the first base structure comprises: two or more core structures separated from one another by one or more vias; one or more redistribution layers formed over a surface of the core structure, wherein the one or more redistribution layers comprise redistribution layer vias disposed therein; and an interconnect panel. Then forming a first conductive layer within the formed patterning layer; removing the patterning layer after forming the first conductive layer; forming an outer dielectric layer over portions of the formed first conductive layer; depositing a second conductive layer over the outer dielectric layer and exposed portions of the first conductive layer; forming conductor features by removing a portion of the second conductive layer to expose surfaces of the outer dielectric layer and surfaces of the second conductive layer; and bonding an electronic component to one or more of the conductor features using a copper alloy interconnect formed over the conductive features.

The preceding discussion found in the Detailed Description is directed to various embodiments. However, one of ordinary skill in the art will understand that the examples disclosed herein have broad application, and that the discussion of any embodiment is meant only to be exemplary of that embodiment, and not intended to suggest that the scope of the disclosure, including the claims, is limited to that embodiment.

The drawing figures are not necessarily to scale. Certain features and components herein may be shown exaggerated in scale or in somewhat schematic form and some details of conventional elements may not be shown in interest of clarity and conciseness.

Any one or more components of the various embodiments disclosed herein may be integrally formed together, directly coupled together, and/or indirectly coupled together and are not limited to the specific arrangement of components illustrated in FIGS. 1-4. Any one or more of the components, embodiments, or steps of the embodiments disclosed herein may be combined in whole or part with any other components, embodiments, or steps of the embodiments disclosed herein. Specifically, it should be appreciated that the use of heterogenous copper interconnects as described throughout is not limited to the various embodiments disclosed herein. The broad application of the heterogenous copper interconnects is the versatility of the heterogenous copper interconnects applicability to be used in multiple process environments to bond materials of different types to one another.

Certain embodiments and features have been described using a set of numerical upper limits and a set of numerical lower limits. It should be appreciated that ranges including the combination of any two values, e.g., the combination of any lower value with any upper value, the combination of any two lower values, and/or the combination of any two upper values are contemplated unless otherwise indicated. Certain lower limits, upper limits, and ranges appear in one or more claims below.

In the preceding discussion and in the claims, the terms “including” and “comprising” are used in an open-ended fashion, and thus should be interpreted to mean “including, but not limited to . . . ” Also, the term “couple” or “couples” is intended to mean either an indirect or direct connection. Thus, if a first device couples to a second device, that connection may be through a direct connection of the two devices, or through an indirect connection that is established via other devices, components, nodes, and connections.

Certain embodiments and features have been described using the term “about,” “generally,” “substantially,” and/or “generally.” When any of these terms are used in conjunction with a numerical value, it should be construed as indicating any numerical value within 10% of the stated numerical value.

While the foregoing is directed to embodiments of the present disclosure, other and further embodiments of the disclosure may be devised without departing from the basic scope thereof, and the scope thereof is determined by the claims that follow.

What is claimed is:

1. A method of forming an advanced package assembly, comprising:
depositing a first conductive layer over a surface of and within features formed in a patterned dielectric layer that is formed over a first base structure, wherein the first base structure comprises a core structure over which the patterned dielectric layer is formed;
forming conductor features by removing a portion of the first conductive layer, wherein removing the portion of the first conductive layer exposes the surface of the patterned dielectric layer and portions of the first conductive layer formed within the features formed in the patterned dielectric layer;
depositing a second conductive layer on exposed surfaces of the first conductive layer formed within the features, wherein the first conductive layer comprises copper, and the second conductive layer comprises an alloy of copper; and
forming a bond between an electrical contact of an electronic component and the second conductive layer, wherein the electrical contact comprises copper.

2. The method of claim 1, wherein the first base structure further comprises one or more redistribution layers formed on a surface of the core structure, wherein
the one or more redistribution layers comprise redistribution layer vias that are coupled to vias formed within the core structure,
the patterned dielectric layer that is formed on a surface of the one or more redistribution layers, and
the features formed in a patterned dielectric layer are formed over the redistribution layer vias.

3. The method of claim 2, where the features formed in a patterned dielectric layer are formed by a dynamic digital correction process performed while forming the patterned dielectric layer.

4. The method of claim 2, wherein the first base structure further comprises a bonding dielectric feature comprising a bonding dielectric material that is formed over at least a portion of the exposed surfaces of the patterned dielectric layer formed over the one or more redistribution layers.

5. The method of claim 2, wherein the forming of the bond between an electrical contact of the electronic component and the second conductive layer comprises directly bonding the second conductive layer to a surface of the electrical contact that essentially comprises copper.

6. The method of claim 1, wherein the bonding of the electronic component to one or more of the second conductive layer is performed at a temperature from about 150° C. to about 250° C.

7. The method of claim 1, further comprises:
depositing a third conductive layer on exposed surfaces of the electrical contact, wherein the third conductive layer comprises an alloy of copper; and
wherein the forming of the bond between the electrical contact of the electronic component and the second conductive layer, comprises forming a bond between the third conductive layer and the second conductive layer.

8. An advanced package assembly, comprising:
a base structure comprising:
a core structure comprising a plurality of first vias;
one or more redistribution layers formed over a surface of the core structure, wherein the one or more redistribution layers comprise redistribution layer vias that are each connected to one or more of the first vias;
an interconnect panel;
an outer dielectric layer disposed over the base structure;
one or more conductor features disposed in one or more gaps of the outer dielectric layer;
a first electronic component comprising an inorganic material electrically connected to the base structure; and
a second electronic component comprising an organic material electrically connected to the base structure.

9. The advanced package assembly of claim 8, wherein the electronic components are bonded to the conductor features via at least one copper alloy interconnect.

10. The advanced package assembly of claim 9, wherein the core structure comprises an inorganic material.

11. The advanced package assembly of claim 8, further comprising one or more bonding dielectric features disposed over the outer dielectric layer.

12. The advanced package assembly of claim 8, wherein the interconnect panel is bonded to an interconnect panel of another advanced package assembly via at least one copper alloy interconnect.

13. The advanced package assembly of claim 8, wherein the interconnect panel is bonded to an interconnect panel of a package substrate via at least one copper alloy interconnect.

14. The advanced package assembly of claim 8, further comprising an electronic component bonded to the base structure via at least one solder connection.

15. The advanced package assembly of claim 8, wherein the base structure comprises an organic material and is bonded to an inorganic material via at least one copper alloy interconnect.

16. The advanced package assembly of claim 8, wherein the base structure comprises an inorganic material and is bonded to an inorganic material via at least one copper alloy interconnect.

17. A method of forming an advanced package assembly, comprising:
forming a first base package structure;
bonding the first base package structure to a first electronic component using at least one copper alloy interconnect, wherein the first electronic component comprises an organic material; and
bonding the first base package structure to a second electronic component using at least one copper alloy interconnect, wherein the second electronic component comprises an inorganic material.

18. The method of claim 17, further comprising bonding the first base package structure to a second base package structure using at least one copper alloy interconnect.

19. The method of claim 17, further comprising bonding the first base package structure and a second base package structure to a package substrate via at least one copper alloy interconnect.

20. The method of claim 17, wherein the first electronic component is coupled to the second electronic component or a third electronic component via at least one horizontal copper alloy interconnect.
